(19) United States
(12) Patent Application Publication
(10) Pub. No.: US 2012/0114315 A1
(43) Pub. Date: May 10, 2012

(54) HEAT-DISSIPATING STRUCTURE AND MULTIMEDIA REPRODUCTION DEVICE INCLUDING THE SAME

(76) Inventor: Young-sun Jung, Suwon-si (KR)

(21) Appl. No.: 13/289,257

(22) Filed: Nov. 4, 2011

(30) Foreign Application Priority Data
Nov. 4, 2010 (KR) 10-2010-0109273

(51) Int. Cl. H04N 5/85; H05K 7/20

(52) U.S. Cl. 386/361; 361/704; 386/E05.064

(57) ABSTRACT

An electronic device is provided. The electronic device includes an substrate on which a heat source is mounted, a housing that accommodates the substrate and comprises an upper cover and a lower base disposed above and below the substrate, respectively, and a heat-dissipating structure that is formed in the upper cover, the lower base, or a combination thereof and contacts a side of the substrate.

### CROSS-REFERENCE TO RELATED APPLICATION

This application claims the benefit under 35 U.S.C. §119(a) of Korean Patent Application No. 10-2010-0109273, filed on Nov. 4, 2010, in the Korean Intellectual Property Office, the entire disclosure of which is incorporated herein by reference for all purposes.

### BACKGROUND

1. Field of the Invention

The following disclosure relates to a heat-dissipating structure and a multimedia reproduction device including the same.

2. Description of the Related Art

An electronic device which has heat-generating components mounted on a substrate generally needs to have a heat-dissipating structure. Additional components such as heat sinks or cooling fans may be used, as heat-dissipating structures. However, in compact electronic devices, the additional components make manufacture of compact electronic products more difficult, and thus, development of a compact heat sink for cooling components is needed to simplify manufacturing of the compact electronic devices.

An example of a product that may need heat dissipation and also a compact size is a multimedia reproduction device that includes a system device. The system device may be, for example, a system on chip (SoC).

A multimedia reproduction device may include an SoC as a codec device that processes multimedia sources. The codec device may generate a large amount of heat. Thus, an efficient heat transfer structure or an efficient heat-dissipating structure may be required to dissipate the generated heat.

In general, an AV player, which is an example of a multimedia reproduction device, may independently include an analog sound-image generating device. The analog sound-image generating device may generate sound-image output that is reproduced from a disc based on a disc driving mechanism. A typical multimedia reproducing device may include a dedicated disc driving mechanism.

A 9.5 mm slim-type or half height (H/H) type optical disc drive for a notebook computer or a desktop computer may include a front-end part formed therein and may use a digital processor or the like installed in the computer in order to function as a back-end part to process sound-image signals. Thus, such an optical disc drive may depend upon a computer.

### SUMMARY

According to an aspect, an electronic device is provided. The electronic device includes an substrate on which a heat source is mounted, a housing that accommodates the substrate and comprises an upper cover and a lower base disposed above and below the substrate, respectively, and a heat-dissipating structure that is formed in the upper cover, the lower base, or a combination thereof and contacts a side of the substrate.

An internal surface of the upper cover or the lower base may contact a surface of the heat source.

The heat-dissipating structure may contact a surface of the substrate.

The heat-dissipating structure may be formed on the lower base. At least a portion of the upper cover may contact an upper surface of the heat source.

A thermal conductive layer may be positioned between the heat-dissipating structure and the substrate.

The heat-dissipating structure may protrude away from lowermost portion of the lower base.

The heat-dissipating structure may be integrally formed in the lower base.

The heat-dissipating structure may protrude at least a portion inwardly towards the heat source.

The electronic device may not include a cooling fan or a separate heat-sink structure which the heat source is mounted.

The electronic device may include a heat source.

According to another aspect, a multimedia reproduction device is provided. The multimedia reproduction device includes a substrate on which the heat source is mounted and which comprises an audio unit and a video unit configured to reproduce a voice and video signals output from a signal from an optical disc, a housing that accommodates the substrate and comprises an upper cover and a lower base disposed above and below the substrate, respectively, and a heat-dissipating structure that is formed in the upper cover, the lower base, or a combination thereof, and contacts a side of the substrate.

The multimedia reproduction device may include a motor unit configured to drive an optical disc.

The substrate may include an interface through which audio and image signals are output.

The interface may include a high-definition multimedia interface (HDMI), a universal serial bus (USB), or a combination thereof.

The substrate may include an Ethernet interface.

The optical drive module may be configured to read and/or write data from/to the optical disc.

The optical drive module may conform to the SFF-8552 specification.

According to yet another aspect, an electronic device is provided. The electronic device includes a housing comprising an upper cover and a lower base, a substrate positioned between the upper cover and the lower base and on which a heat source is mounted, and a heat-dissipating structure positioned between the upper cover and the substrate. The electronic device does not include a cooling fan or a separate heat-sink structure which the heat source is mounted.

Other features and aspects may be apparent from the following detailed description, the drawings, and the claims.

### BRIEF DESCRIPTION OF THE DRAWINGS

FIG. 1 is a view illustrating an example of a multimedia reproduction device;

FIG. 2 is a view illustrating an internal structure of the multimedia reproduction device of FIG. 1;

FIG. 3 illustrates an example of a substrate of a multimedia reproduction device, and an upper cover and a lower base respectively placed above and below the substrate in a separated state before being coupled;

FIG. 4 illustrates an example of a substrate of a multimedia reproduction device, and an upper cover and a lower base above and below the substrate, respectively, that are coupled to one another;

FIG. 5 is a view illustrating small form factors (SFF) standards regarding optical disc drives (ODD) for a notebook computer; and

FIG. 6 is a diagram illustrating a multimedia reproduction device.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

The following detailed description is provided to assist the reader in gaining a comprehensive understanding of the methods, apparatuses, and/or systems described herein. Accordingly, various changes, modifications, and equivalents of the systems, apparatuses and/or methods described herein will be suggested to those of ordinary skill in the art. Also, descriptions of well-known functions and constructions may be omitted for increased clarity and conciseness.

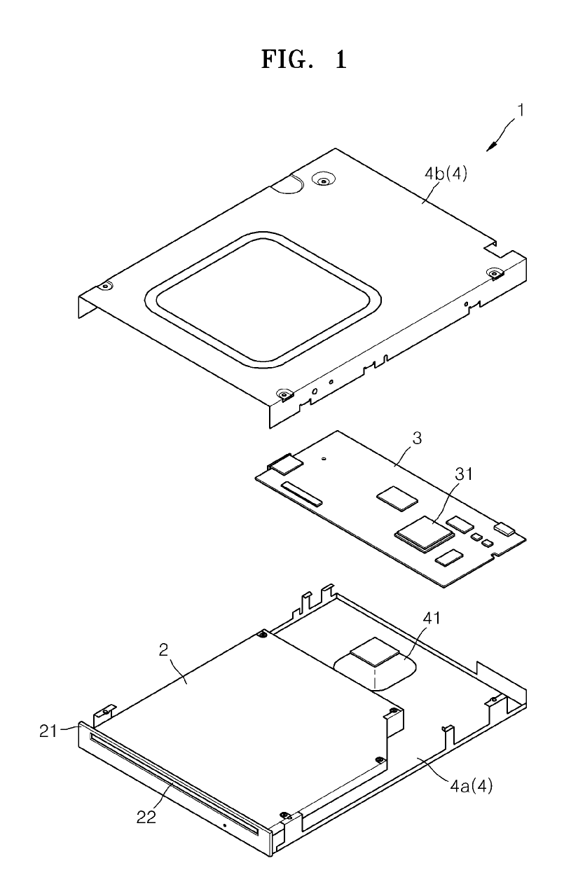

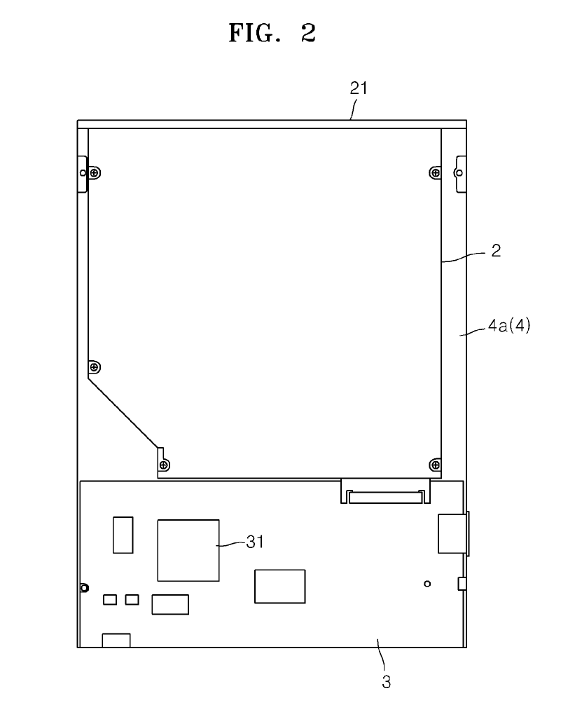

FIG. 1 illustrates an example of a multimedia reproduction device 1 (or an AV player). FIG. 2 illustrates an internal structure of the multimedia reproduction device 1 of FIG. 1 in a coupled state.

Referring to FIGS. 1 and 2, the multimedia reproduction device 1 includes an optical drive module 2, a substrate 3, and a housing 4. The housing 4 may be composed of a lower base 4a and an upper cover 4b.

A panel 21 may be located at a front of the optical drive module 2. A slot 22 may be formed in the panel 21 and through which a disc may be inserted. The optical drive module 2 may be designed for standardized notebook computers and includes components such as an optical pickup, a servo part that controls the optical pickup, and a digital signal processor (DSP) that processes a signal from the optical pickup.

The substrate 3 may include an audio unit, a video unit, or a combination thereof. The substrate may be on a printed circuit board (PCB). The substrate 3 may include a heat source 31 and an output interface. The heat source may be a system on chip (SoC) and may process a signal transmitted from the optical drive module 2. The output interface may output a voice-image signal.

The housing 4 may be formed of a highly thermally conductive material such as, for example, a metal plate. The housing 4 may be formed to accommodate the optical disc module 2 and the substrate 3, may include the lower base 4a that has a inwardly protruding heat-dissipating structure 41 (also referred to as a heat transfer or cooling structure) and may include the upper cover 4b. The heat-dissipating structure 41 may be stamped, punched or otherwise processed into the lower base 4a. The heat-dissipating structure 41 may also be integrally formed in the lower base 4a. The lower base 4a may contact a lower surface of the substrate 3 in order to dissipate heat generated by the heat source 31. The upper cover may protect the lower base 4a, the optical disc module 2, and the substrate 3 that are installed on the lower base 4a. The heat-dissipating structure may protrude from the lower base 4a towards the upper cover 4b.

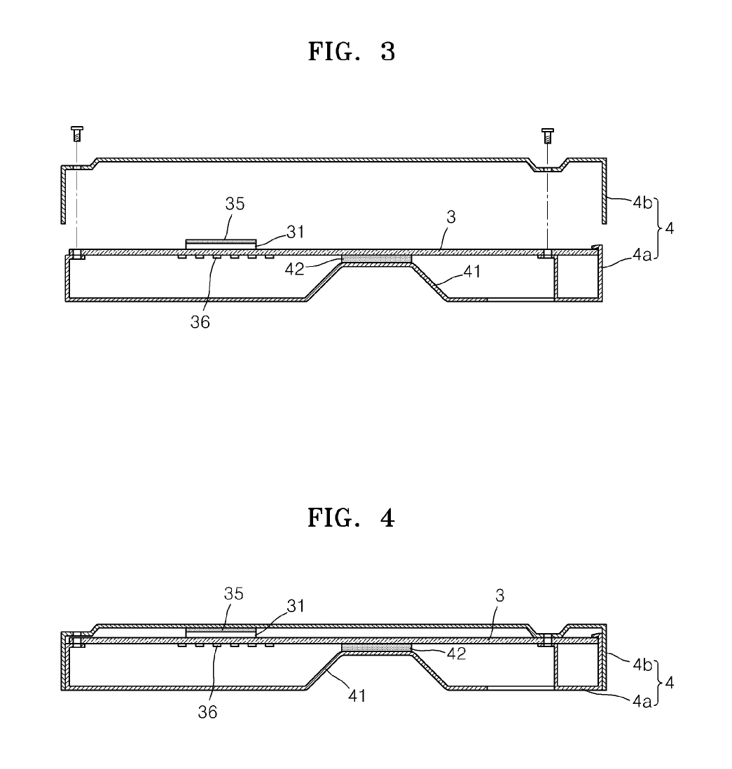

FIG. 3 illustrates the substrate 3 of the multimedia reproduction device 1 and the upper cover 4b and the lower base 4a placed above and below the substrate 3, respectively, in a separated state before being coupled. The multimedia reproduction device may be an example of an electronic device. FIG. 4 illustrates a partial cross-sectional view of the upper cover 4b and the lower base 4a of the multimedia reproduction device 1 coupled to one another.

Referring to FIGS. 3 and 4, the lower base 4a and the upper cover 4b are coupled to each other with the substrate 3 interposed between the lower base 4a and the upper cover 4b. The heat-dissipating structure 41 of the lower base 4a may contact the lower surface of the substrate 3. As a selective element, a first insulating thermal conductive layer 42 may be sandwiched between the heat-dissipating structure 41 and the substrate 3. The first insulating thermal conductive layer 42 may electrically insulate the heat-dissipating structure 41 and the substrate 3. The heat-dissipating structure 41 may be located away from the heat source 31 because an electronic component 36 may be inevitably disposed below the heat source 31. In other words, a cooling structure may contact a free portion of the substrate 3 if the cooling structure cannot be directly placed under the heat source 31 of an electronic device. Moreover, this structure may be used when the heat source 31 contacts the upper cover 4b. A second insulating thermal conductive layer 35 may be sandwiched between the heat source 31 and the upper cover 4b as another selective element. The multimedia reproduction device 1 may include the first insulating thermal conductive layer, the second insulating thermal conductive layer or a combination thereof.

As described above, the heat-dissipating structure of the multimedia reproduction device may be formed using body portions of the housing 4. The heat-dissipating structure does not require any additional elements. Accordingly, the heat-dissipating structure allows the electronic device and the multimedia reproduction devices using the electronic device to be minimized without a limitation in size.

According to another example of the heat-dissipating structure, the optical drive module 2 of the multimedia reproduction device 1 may have a structure that complies with small form factors (SFF)-8552 specifications, and in particular, may have a slim structure, which are hereby incorporated by reference.

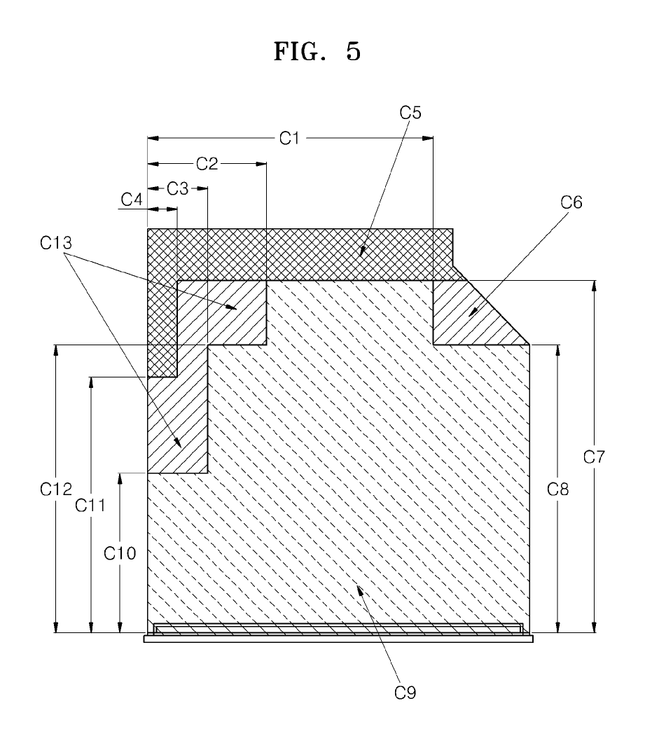

FIG. 5 illustrates a part of a blueprint of a 9.5 mm slim type optical disc drive (ODD) defined by (SFF)-8552, showing all dimensions of the elements illustrated in FIGS. 1 through 3. An example of details can be found at SFF-8552 Rev 1.4 RC.

TABLE 1

| | Dimension | Tolerance |
|---|---|---|
| Designator | (mm) | (mm) |
| A1 | 97.40 | ±.20 |
| A2 | 65.10 | ±.20 |
| A3 | 52.60 | ±.20 |
| A4 | 21.25 | ±.30 |
| A5 | 3.80 | ±.20 |
| A6 | 6.00 | ±.30 |
| A7 | 6.15 | ±.30 |
| A8 | 4X M2 | Depth 1.5 |
| | | Min |
| A9 | 3X 3.20 | ±.20 |
| A10 | 128.00 | ±.20 |
| A11 | 102.60 | ±.20 |
| A12 | 9.50 | +.50/−.20 |
| A13 | 3X 2.30 | ±.20 |
| A14 | 3X M2 | Depth 1.5 |
| | | Min |
| A15 | 89.85 | ±.85 |
| A16 | 114.65 | ±.75 |
| A17 | 110.10 | ±.20 |
| A18 | 27.30 | ±.20 |
| A19 | 5.30 | ±.20 |
| A20 | 4.60 | ±.20 |
| A21 | XXX | ±.30 |
| A22 | 126.00 | Max |
| A23 | 2.00 | Min |
| A24 | XXX | ±.30 |
| A25 | 126.10 | ±.20 |
| A26 | 27.30 | ±.20 |
| A27 | 110.10 | ±.20 |
| A28 | 2X M2 | Depth 1.5 |
| | | Min |
| A29 | 2X 6.80 | ±.20 |
| A30 | 3.60 | ±.30 |
| A31 | | |
| A32 | 3.00 | Max |
| A33 | 10.50 | Max |
| A34 | 0.90 | ±.20 |
| A35 | 90.0 | ±3.0 |
| | degrees | degrees |
| A36 | XXX | ±.30 |
| B1 | 0.90 | |
| B2 | 12.00 | |
| B3 | 0.00 | |
| C1 | 96.20 | |
| C2 | 40.00 | |
| C3 | 20.00 | |
| C4 | 10.00 | |
| C5 | Less than | Newtons |
| | 1 | |
| C6 | Less than | Newtons |
| | 0.5 | |
| C7 | 110.00 | |
| C8 | 90.00 | |
| C9 | 0.00 | Newtons |
| C10 | 50.00 | |
| C11 | 80.00 | |
| C12 | 90.00 | |
| C13 | Less than | Newtons |
| | 0.5 | |

By conforming to the external forms and dimensions presented above, various ODDs of different companies may be applied to notebook computers regardless of the ODD manufacturers.

However, notebook computer-only ODDs may not be applied to other application devices. A compact multimedia reproduction device which can be manufactured at a lower cost in comparison to a conventional compact multimedia reproduction device by forming an efficient heat dissipating (cooling) structure when designing an ODD for currently manufactured smart televisions may be developed. ODDs for notebook computers, including ODDs conforming to SFF-8552, may be mounted as an optical drive module of a multimedia reproduction device. Accordingly, in response to designing a multimedia reproduction device, an additional optical drive module may be excluded, and thus, design costs may be reduced. Moreover, a single-piece optical drive module may be used not only in a notebook computer but also in a multimedia reproduction device, thereby reducing manufacturing costs.

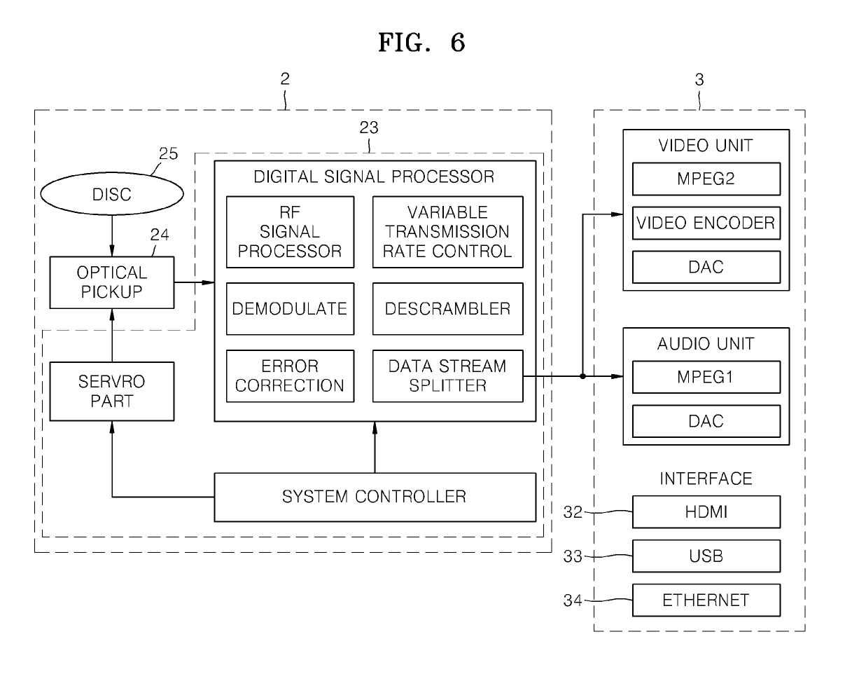

FIG. 6 illustrates an example of a multimedia reproduction device.

As illustrated in FIG. 6, an optical drive module 2 may include an optical pickup 24 that reads or writes data from a disc 25 and a front-end part 23. The front-end part 23 includes a servo unit 231 that controls the optical pickup 24 and a digital signal processor (DSP), a demodulating unit, an error correction unit, a variable transmission rate control unit, descrambler and a stream (data) splitter. The DSP may include an RF signal processor that processes a signal transmitted from the optical pickup 24.

A substrate 3 may individually decode an audio signal and a video signal from the front-end part 23 using an MPEG decoder and may convert the audio and video signals using a digital-analog converter (DAC) to output an analog audio-video signal.

According to another example of the multimedia reproduction device, a high-definition multimedia interface (HDMI) 32 may be included in the substrate 3 as an interface for inputting/outputting the audio/video signal. Also, according to another example of the multimedia reproduction device, the substrate 3 may include an Ethernet device 34 for downloading content streams from the Internet. According to yet another example of the multimedia reproduction device, the substrate 3 may further include a universal serial bus (USB) 33 for controlling the whole system.

According to yet another example of the multimedia reproduction device, the optical drive module 2 may reproduce not only data stored on CD/DVD but also data store on Blu-ray.

The optical drive module in the above examples may have a slot-in type disc transporting structure. However, a tray type transporting structure may also be used. The optical drive modules may reproduce data from a disc, and furthermore, may write data to the disc.

According to the examples of the multimedia reproduction device, heat is dissipated (discharged) via a structure of a housing from a codec chip of a microprocessor or a multimedia reproduction device which generates a large amount of heat. Accordingly, according to the examples of the multimedia reproduction device, an additional heat-dissipating structure or a cooling structure such as a heat sink or a cooling fan is not required. An electronic device including the heat-dissipating structure may be a multimedia reproduction device. Also, when forming a multimedia reproduction device having the above-described structure, an additionally designed optical drive module (or an optical disc drive) may be excluded. That is, standardized optical disc drives for notebook computers may be used without any substantial change. Thus, optical disc drives that comply with standards may be applied to the multimedia reproduction device regardless of the manufacturer. The heat-dissipating structure lowers costs for users as well as manufacturers. For example, users may replace optical disc drives having the greatest number of error factors, if necessary.

Accordingly, a new structure including front-end and parts installed therein may be developed. In this case, a heat-dissipating (cooling) structure for dissipating heat in, for example, an SoC installed in a part is developed.

The units described herein may be implemented using hardware components and software components. For example, microphones, amplifiers, band-pass filters, audio to digital convertors, and processing devices. A processing device may be implemented using one or more general-purpose or special purpose computers, such as, for example, a processor, a controller and an arithmetic logic unit, a digital signal processor, a microcomputer, a field programmable array, a programmable logic unit, a microprocessor or any other device capable of responding to and executing instructions in a defined manner. The processing device may run an operating system (OS) and one or more software applications that run on the OS. The processing device also may access, store, manipulate, process, and create data in response to execution of the software. For purpose of simplicity, the description of a processing device is used as singular; however, one skilled in the art will appreciated that a processing device may include multiple processing elements and multiple types of processing elements. For example, a processing device may include multiple processors or a processor and a controller. In addition, different processing configurations are possible, such a parallel processors. A number of examples have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. An electronic device comprising:
a substrate on which a heat source is mounted;
a housing that accommodates the substrate and comprises an upper cover and a lower base disposed above and below the substrate, respectively; and
a heat-dissipating structure that is formed in the upper cover, the lower base, or a combination thereof and contacts a side of the substrate.

2. The electronic device of claim 1, wherein an internal surface of the upper cover or the lower base contacts a surface of the heat source.

3. The electronic device of claim 1, wherein the heat-dissipating structure contacts a surface of the substrate.

4. The electronic device of claim 3, wherein the heat-dissipating structure is formed on the lower base, and
wherein at least a portion of the upper cover contacts an upper surface of the heat source.

5. The electronic device of claim 1, wherein a thermal conductive layer is positioned between the heat-dissipating structure and the substrate.

6. The electronic device of claim 1, wherein the heat-dissipating structure protrudes away from lowermost portion of the lower base.

7. The electronic device of claim 1, wherein the heat-dissipating structure is integrally formed in the lower base.

8. The electronic device of claim 1, wherein the heat-dissipating structure protrudes at least a portion inwardly towards the heat source.

9. The electronic device of claim 1, wherein the electronic device does not include a cooling fan or a separate heat-sink structure which the heat source is mounted.

10. A multimedia reproduction device comprising:
a substrate on which the heat source is mounted and which comprises an audio unit and a video unit configured to reproduce a voice and video signals output from a signal from an optical disc;
a housing that accommodates the substrate and comprises an upper cover and a lower base disposed above and below the substrate, respectively; and
a heat-dissipating structure that is formed in the upper cover, the lower base, or a combination thereof, and contacts a side of the substrate.

11. The multimedia reproduction device of claim 10, further comprising a motor unit configured to drive an optical disc.

12. The multimedia reproduction device of claim 10, wherein the substrate further comprises an interface through which audio and image signals are output.

13. The multimedia reproduction device of claim 12, wherein the interface comprises a high-definition multimedia interface (HDMI), a universal serial bus (USB), or a combination thereof.

14. The multimedia reproduction device of claim 13, wherein the substrate comprises an Ethernet interface.

15. The multimedia reproduction device of claim 10, wherein the substrate comprises an Ethernet interface.

16. The multimedia reproduction device of claim 11, wherein the optical drive module is configured to read and/or write data from/to the optical disc.

17. The multimedia reproduction device of claim 16, wherein the optical drive module conforms to the SFF-8552 specification.

18. The multimedia reproduction device of claim 12, wherein the optical drive module conforms to the SFF-8552 specification.

19. The multimedia reproduction device of claim 13, wherein the optical drive module conforms to the SFF-8552 specification.

20. An electronic device comprising:
a housing comprising an upper cover and a lower base;
a substrate positioned between the upper cover and the lower base and on which a heat source is mounted; and
a heat-dissipating structure positioned between the upper cover and the substrate, wherein the electronic device does not include a cooling fan or a separate heat-sink structure which the heat source is mounted.

21. The electronic device of claim 1, further comprising a heat source.
